(19) United States
(12) Patent Application Publication
(10) Pub. No.: US 2009/0017582 A1
(43) Pub. Date: Jan. 15, 2009

(54) METHOD FOR MANUFACTURING SEMICONDUCTOR DEVICE

(75) Inventor: MUTSUMI MASUMOTO, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/168,637

(22) Filed: Jul. 7, 2008

(30) Foreign Application Priority Data
Jul. 9, 2007 (JP) 2007-179461

(51) Int. Cl. H01L 21/56

(52) U.S. Cl. 438/127; 257/E21.502

(57) ABSTRACT

This invention includes a method for manufacturing a semiconductor device by which implementation of a finer pitch for a semiconductor chip can be handled, and the creation of voids inside an under-filling resin can be reduced in order to realize highly reliable flip-chip mounting. It involves a step in which multiple electrodes arranged two-dimensionally on one side of a semiconductor chip are connected to corresponding conductive regions on a substrate; a step in which an under-filling resin is injected between the one surface of the semiconductor chip and the substrate; and a step in which the under-filling resin is melted at a temperature higher than its glass transition temperature while under a prescribed pressure and cured.

### FIELD OF THE INVENTION

The present invention pertains to a method for filling an underfill. In particular, it pertains to the reduction or extinction of voids or bubbles in an under-filling resin.

### BACKGROUND OF THE INVENTION

Due to advancements in portable telephones, portable computers, and other compact electronic equipment, demands are increasing for the installation of highly integrated semiconductor devices in these devices and for narrower pitches. Flip-chip mounting of a semiconductor chip on a substrate is available so meet such demands. In the case of flip-chip mounting, bump electrodes formed on a primary surface as an integrated circuit plane of a semiconductor chip are directly connected face-to-face to electrodes or lands that are formed on a substrate. This kind of flip-chip mounting replaces the method in which electrodes of a semiconductor chip are connected to a substrate by means of wire bonding.

For example, Patent literature 1 discloses a method in which a semiconductor chip is flipped or placed face down, and an under-filling treatment is applied between a substrate and the semiconductor chip in order to produce a BGA package. In addition, Patent literature 2 discloses a technique in which an under-filling resin is injected between one of the primary surfaces of a semiconductor chip and a substrate so as to restrain the creation of voids inside the under-filling resin in order to present a highly reliable flip-chip mounting.

(Patent literature 1) Japanese Kokai Patent Application No. Hei 11[1999]-345837
(Patent literature 2) Japanese Kokai Patent Application No. 2007-103772

During flip-chip mounting, as shown in FIG. 8, for example, stud bump electrodes 12 are formed on a surface of semiconductor chip 10 at pitch P, and on the other hand, copper patterns 14 are formed on substrate 16 so as to match said pitch P. Ball-shaped solder bumps 18 are formed on copper patterns 14 by means of solder plating, they are joined together by sticking stud bump electrodes 12 into solder bumps 18, and solder bumps 18 are melted in order to alloy the joint parts. Subsequently, liquid resin 20 for under-filling is injected between semiconductor chip 10 and substrate 16 in order to prevent breaking off of the joints due to concentration of stress at stud bump electrodes 12 and solder bumps 18. Under-filling resin 20 advances to the depth of the gap between the semiconductor chip and the substrate by capillary means in order to resin-seal the surface where the semiconductor chip and the substrate are joined together.

However, under-filling resin 20 may not be sufficiently distributed close to the center of the semiconductor chip due to various factors; or even if it is distributed sufficiently, under-filling resin 20 sometimes includes voids 22, such as bubbles inside the resin, as shown in FIG. 9. Voids 22 can be up to 40-50 microns in size. Effects of the physical size and the shape of the semiconductor chip may be considered a factor in the formation of such voids. For example, if pitch P of the electrodes of the semiconductor chip is reduced to 50 μm, several tens to several hundreds of electrodes are used, or if distance D between the semiconductor chip and the substrate is 50 μm or less, resistance or blockage against the advancement of the resin is increased, so the speed of advancement of the resin inside is uneven. As a result, voids are created because the resin takes bubbles in. Once many voids have been created inside the resin, cracks are readily created in the resin, the stress buffering effect of the resin is degraded, and the connections between the electrodes are readily broken off. In particular, when distance D is reduced, a load applied to one electrode is increased due to the difference between the thermal expansion coefficient of the semiconductor chip and that of the substrate, and a higher level of stress is also applied to the under-filling resin. In addition, when cracks are created in the resin, insufficient protection is provided against water and moisture from the outside.

The intent of the present invention is to solve the aforementioned conventional problems, and its objective is to present a method for manufacturing a semiconductor device by which implementation of a finer pitch for a semiconductor chip can be handled, and the creation of voids inside an under-filling resin can be reduced in order to realize highly reliable flip-chip mounting.

### SUMMARY OF THE INVENTION

The method for manufacturing a semiconductor device pertaining to the present invention involves a step in which multiple electrodes arranged two-dimensionally on one side of a semiconductor chip are connected to corresponding conductive regions on a substrate; a step in which an under-filling resin is injected between the one surface of the semiconductor chip and the substrate; and a step in which the aforementioned under-filling resin is melted under a prescribed pressure, and the aforementioned under-filling resin is cured. Here, the multiple electrodes of the semiconductor chip may include bumps made of Au or solder, for example. Similarly, the conductive regions of the substrate may include bumps made of Au or solder.

Preferably, the under-filling resin is heated to a temperature higher than its glass transition temperature in the curing step. The under-filling resin is an epoxy resin filled with silica, for example. In this case, the melt viscosity of the under-filling resin is 60 Pa·s or higher. In addition, the gap between the one surface of the semiconductor chip and the substrate surface is 50 microns or less. The multiple electrodes of the semiconductor chip are especially effective when they are arranged at a pitch of 50 microns or less.

Furthermore, the manufacturing method may include a step in which a liquefied under-filling resin is cured. Moreover, the manufacturing method may include a step in which the substrate injected with the under-filling resin is placed inside a chamber, and the under-filling resin is melted inside the chamber during the melting step. During the injection step, the under-filling resin may be injected from the side of one side surface of the semiconductor chip, or the under-filling resin may be injected from a diagonal direction.

Furthermore, the method for manufacturing a semiconductor device of the present invention involves a step in which multiple electrodes arranged two-dimensionally on one side of a semiconductor chip are connected to corresponding conductive regions on a substrate; a step in which an under-filling resin is injected between the one surface of the semiconductor package and the substrate; and a step in which the aforementioned under-filling resin is melted under a prescribed pressure, and the aforementioned under-filling resin is cured.

Furthermore, the method for manufacturing a semiconductor device of the present invention involves a step in which multiple electrodes arranged two-dimensionally on one side of one semiconductor package are connected to corresponding conductive regions on another semiconductor package; a step in which an under-filling resin is supplied between one surface of the one semiconductor package and one surface of the other semiconductor package; and a step in which the aforementioned under-filling resin is melted under a prescribed pressure, and the aforementioned under-filling resin is cured.

### BRIEF DESCRIPTION OF THE DRAWINGS

FIG. 1 is a diagram showing the steps for manufacture of a semiconductor device pertaining to an embodiment of the present invention.

FIG. 2 shows plan views of semiconductor chip electrode pattern examples.

FIG. 3 shows cross-sectional views of an example of a semiconductor chip and a substrate used for flip-chip mounting.

FIG. 4 is a table showing characteristics of epoxy resins used as under-filling resins.

FIG. 5 shows diagrams showing possible directions for injection of an under-filling resin.

FIG. 6 is a diagram for explaining another example of flip-chip mounting.

FIG. 7 is a diagram for explaining another example of flip-chip mounting.

FIG. 8 is a diagram for explaining a problem of conventional flip-chip mounting.

FIG. 9 is a schematic plan view of created voids.

### REFERENCE NUMERALS AND SYMBOLS AS SHOWN IN THE DRAWINGS

In the figures, 100 represents a semiconductor chip, 110 represents a primary surface, 120 represents an electrode, 130 represents a bump, 200 represents a substrate, 210 represents a top surface, 220 represents an electrode, 230 represents a solder bump, 240 represents an internal wiring, 250 represents a back surface, 260 represents an external electrode, 270 represents a solder ball, 300 represents an under-filling resin, 400 represents a semiconductor package, 410 represents an external terminal, 500 represents a first semiconductor package, 600 represents a second semiconductor package.

### DESCRIPTION OF THE EMBODIMENTS

According to the present invention, because the under-filling resin is melted under a prescribed pressure, voids such as bubbles created in the resin are dispersed inside the melted resin, and the presence of the voids inside the resin can be practically ignored as a result. Preferably, the voids may exist to such an extent that they cannot be observed by the naked eye or using an ultrasonic image analyzer.

A preferred embodiment of the present invention will be explained in detail below with reference to figures. Here, a flip-chip-mounted semiconductor device will serve as the example.

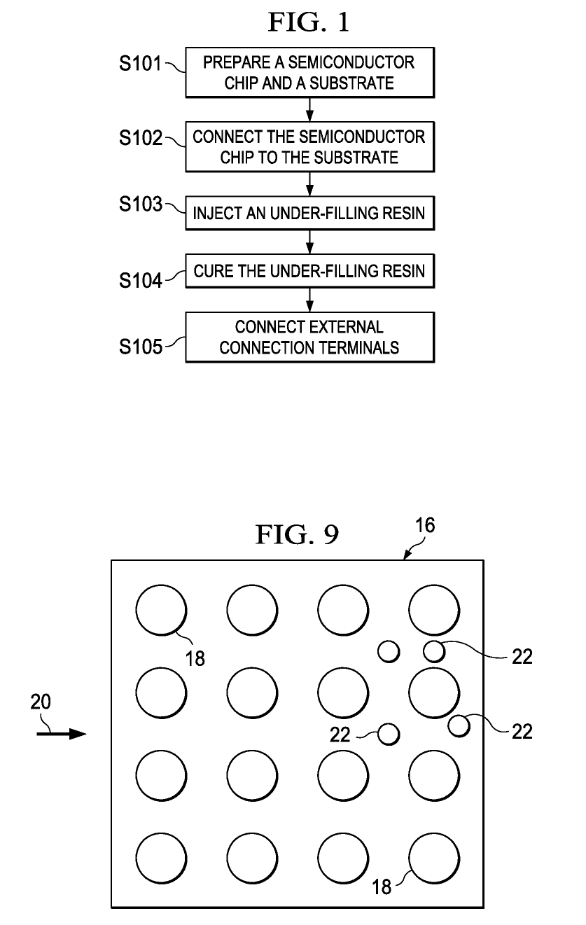

FIG. 1 is a flow chart of a method for manufacturing a semiconductor device pertaining to an embodiment of the present invention. The manufacturing method of the present embodiment includes a step (Step S101) in which a semiconductor chip and a substrate are prepared, a step (Step S102) in which electrodes of the semiconductor chip are flip-chip-connected to conductive patterns formed on the substrate, a step (Step S103) in which an under-filling resin is injected into a gap formed between the semiconductor chip and the substrate, a step (Step S104) in which the under-filling resin is cured, and a step (Step S105) in which external connection terminals are connected.

Multiple electrodes are formed on one surface of the semiconductor chip to be flip-chip-connected. The electrodes are Au or solder bumps formed by means of plating or paste printing, or they are Au stud bumps formed by capillary means; or they may include such bumps. Obviously, the shape, the size, and the material of the electrodes are not restricted to those described in the aforementioned example as long as flip-chip mounting or face-down mounting can be utilized.

The multiple electrodes are arranged two-dimensionally, and they are connected electrically to a circuit element formed on the surface of a silicon substrate. Although a great benefit of the present embodiment can be enjoyed when a fine electrode pitch such as 50 microns or less is adopted, the electrode pitch may be greater than 50 microns.

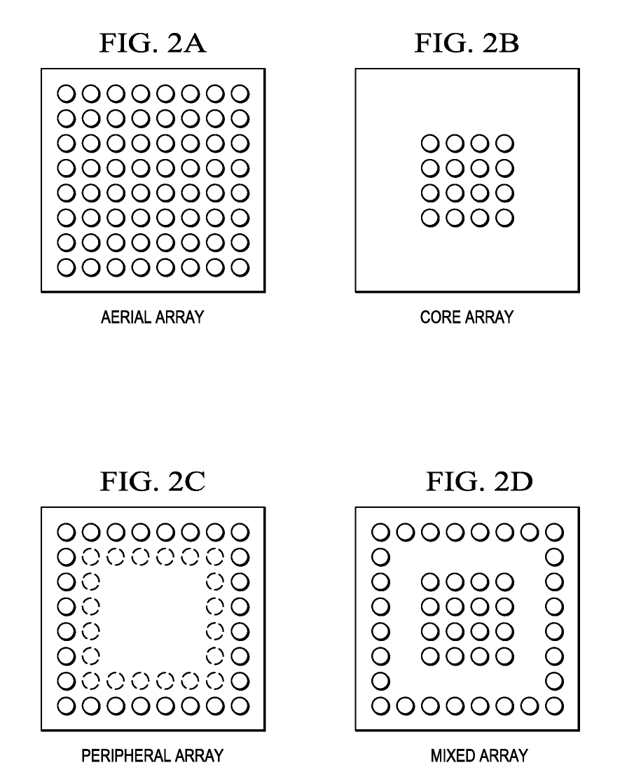

Several electrode arrangement patterns are shown in FIG. 2. FIG. 2(a) shows an aerial array, wherein multiple electrodes are arranged in the form of a matrix over almost the entire surface of the semiconductor chip. FIG. 2(b) shows a core array, wherein multiple electrodes are arranged in the form of a matrix at the center part of the semiconductor chip. FIG. 2(c) shows a peripheral array, wherein a single row or multiple rows of electrodes are arranged at the periphery of the semiconductor chip. FIG. 2(d) shows a mixed array, wherein a core array and a peripheral array are present in a mixed fashion. The above are example semiconductor chips, and electrode arrangements other than those shown here may be adopted.

A polyimide substrate or a ceramic substrate may be used as a substrate for a flip-chip, and a multilayer wiring board may be utilized to this end. For example, a laminate substrate made of a glass epoxy resin or a polyimide resin may be used. Conductive patterns to be connected to the electrodes of the semiconductor chip are formed on the surface of the substrate. The conductive patterns constitute conductive regions where Cu patterns, Cu patterns plated with solder, or bumps made of solder may be formed.

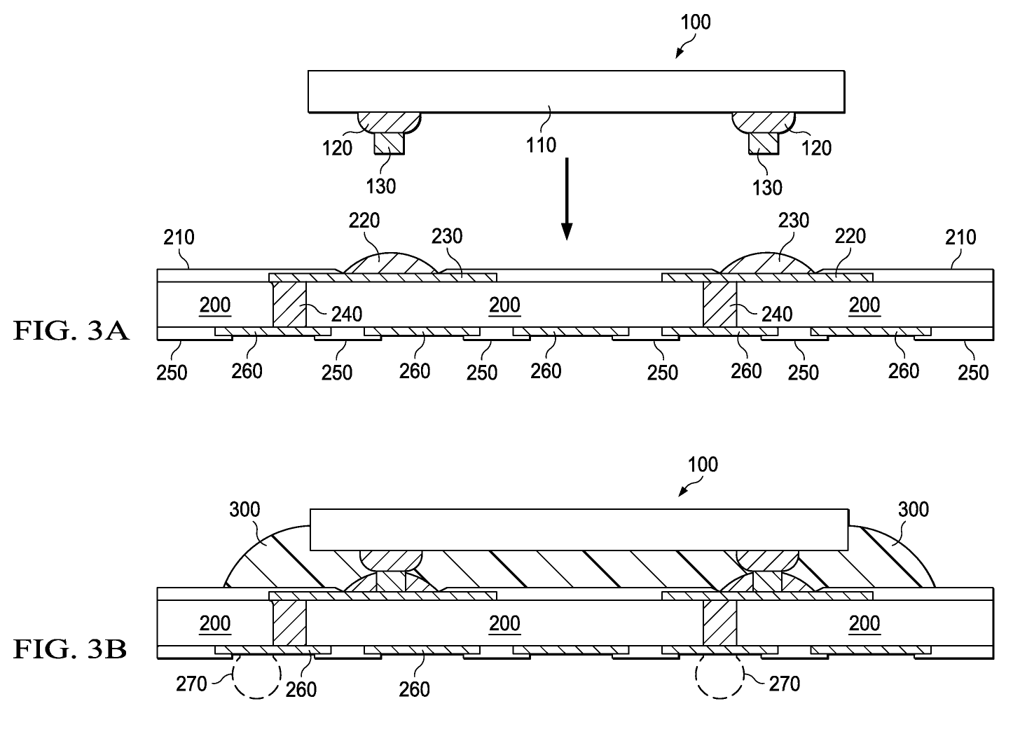

FIG. 3 shows cross-sectional views of an example of a semiconductor chip and a substrate used for flip-chip mounting. Multiple aluminum electrode pads 120 are formed on primary surface 110 as an integrated circuit plane of semiconductor chip 100. Bumps 130 are connected to electrode pads 120. For example, bumps 130 are Au stud bumps, and their diameter is approximately 35 μm. Preferably, 440 units of electrode pads 130 are arranged at a pitch of 50 μm.

Electrodes 220 made of Cu, for example, are formed on top surface 210 of substrate 200; slightly protruding solder bumps 230 are formed on electrodes 220. Solder bumps 230 are provided at positions that correspond to electrode pads 120 or bumps 130 of semiconductor chip 100. Electrodes 220 are connected to external electrodes 260 that are formed on back surface 250 of the substrate, via internal wiring 240 of substrate 200.

Bumps 130 of semiconductor chip 100 are connected to solder bumps 230 of substrate 200, and bumps 130 and electrodes 220 are bonded together eutecticly by means of solder reflow. At this time, the distance between primary surface 110 of semiconductor chip 100 and top surface 210 of substrate 200 is approximately 15 microns.

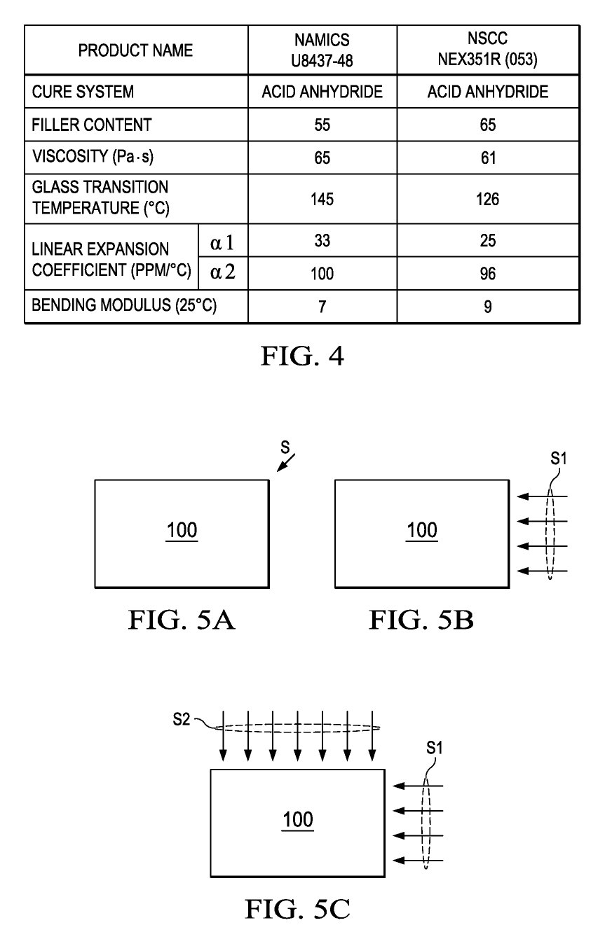

Next, because connections between bumps 130 and electrodes 230 are brittle, under-filling resin 300 is injected in the gap formed between primary surface 110 of semiconductor chip 100 and substrate 200 for the purpose of reinforcement. Preferably, an epoxy resin that has a low level of viscosity at a given temperature may be used as under-filling resin 300. For example, Namics U8437-48 or NSCC NEX-351 R (053) can be used to this end. FIG. 4 is a table showing characteristics of said epoxy resins. For example, Namics contains 55 wt % silica particles, and its viscosity is 65 Pa·s. NSCC contains 65 wt % silica particles, and its viscosity is 61 Pa·s.

The under-filling resin is injected at a temperature at which the epoxy resin is liquefied. Preferably, it is heated to a temperature higher than its glass transition temperature. The position and the direction of injection of the under-filling resin are selected based on the shape and the size of the semiconductor chip to be flip-chip-mounted, the number of electrodes involved, and the arrangement of the electrodes. For example, injection may be from diagonal direction S of semiconductor chip 100 as shown in FIG. 5(a), from direction S1 of one side surface of semiconductor chip 100 as shown in FIG. 5(b), or directions S1 and S2 of 2 adjacent side surfaces of the semiconductor chip as shown in FIG. 5(c).

As described above, under-filling resin 300 advances to the depth through the gap formed between the semiconductor chip and the substrate by capillary means. The advancing speed at this time is uneven due to friction with the semiconductor chip and the substrate surface and hindrance created by the connected electrodes. As a result, the resin ultimately takes air in and voids are created. Especially if the viscosity of the epoxy resin is high, the gap formed between the semiconductor chip and the substrate is narrow, or if the electrodes are arranged at a fine pitch, the probability of creation of voids is increased. In addition, it is impossible to realistically predict the position and size of such voids.

When the number of electrodes involved was 16 (a 4×4 aerial array), the electrodes on the semiconductor side were Au stud bumps, the electrode pitch was 50 microns, the gap between the semiconductor chip and the substrate was 15 microns, and Namics was used as the under-filling resin, it was confirmed that voids at a size of up to 40-50 microns were created inside the under-filling resin. In particular, when stud bump electrodes were used, the shape of the electrodes tended to be uneven, which was considered to be responsible for the creation of the voids. In addition, because variations in the advancing speed of the under-filling resin are intensified while inside when the mixed array shown in FIG. 2(d) is used as the electrode pattern, some increase in the probability of creation of internal voids can be anticipated.

In the present embodiment, the under-filling resin is cured in order to virtually eliminate such voids. When the under-filling resin is injected, the under-filling resin advances inside the gap formed between the semiconductor chip and the substrate by capillary means; and once the injection has been completed, the under-filling resin hardens for the moment. Next, the under-filling resin is cured. Although it is desirable to inject and cure the under-filling resin in succession, it does not necessarily interfere if another process is carried out in the meantime.

During the curing, under-filling resin 300 is melted by heating it to a temperature higher than its glass transition temperature while a prescribed level of pressure is applied to it. When the resin is melted while pressure is applied, voids are allowed to move inside the resin, so the voids created inside the resin are dispersed inside the liquefied resin or are purged from the resin. In addition, the pressure can be changed as needed according to the material properties (for example, viscosity) of the under-filling resin, the shape and the size of the semiconductor chip, the electrode pitch, the electrode pattern, and the gap formed between the semiconductor chip and the substrate.

Because the voids created inside the resin are segmented, miniaturized, or purged as a result of the aforementioned curing, they can be brought to a state where they cannot be observed by the naked eye or by using an SAT (an ultrasonic image analyzer). As a result, deterioration of the resin strength by voids, and cracks attributable to the voids are eliminated, so the presence of the voids can be virtually ignored.

Preferably, a pressure chamber equipped with a heating function can be used for curing. The substrate filled with the under-filling resin is placed inside the pressure chamber, the inside of the chamber is then set at a prescribed pressure, and the inside of the chamber is heated to a temperature higher than the glass transition of the under-filling resin temperature in order to cure it. For example, when Namics shown in FIG. 4 is used, the curing temperature is set at 175°, which is higher than its glass transition temperature of 145°; and the pressure inside the chamber is set at 0.5 Mpa. The curing time is approximately 1 hour. Although the viscosity of Namics is relatively high, when the aforementioned curing is applied, virtually no voids will be present inside the resin.

After the under-filling resin has been cured, solder balls 270 for BGA or CSP are connected to external electrodes 260 on back surface 250 of substrate 200. Obviously, in the case of an LGA (Land Grid Array), external electrodes 260 are used as external electrodes, so solder balls do not have to be connected. When multiple chips are mounted on substrate 200, the substrate is cut by the unit of each semiconductor chip.

As described above, when the under-filling resin is cured during flip-chip mounting, voids in the under-filling resin can be eliminated, whereby separation between the semiconductor chip and the substrate can be restrained, so that a highly reliable semiconductor device that accommodates a fine pitch can be presented.

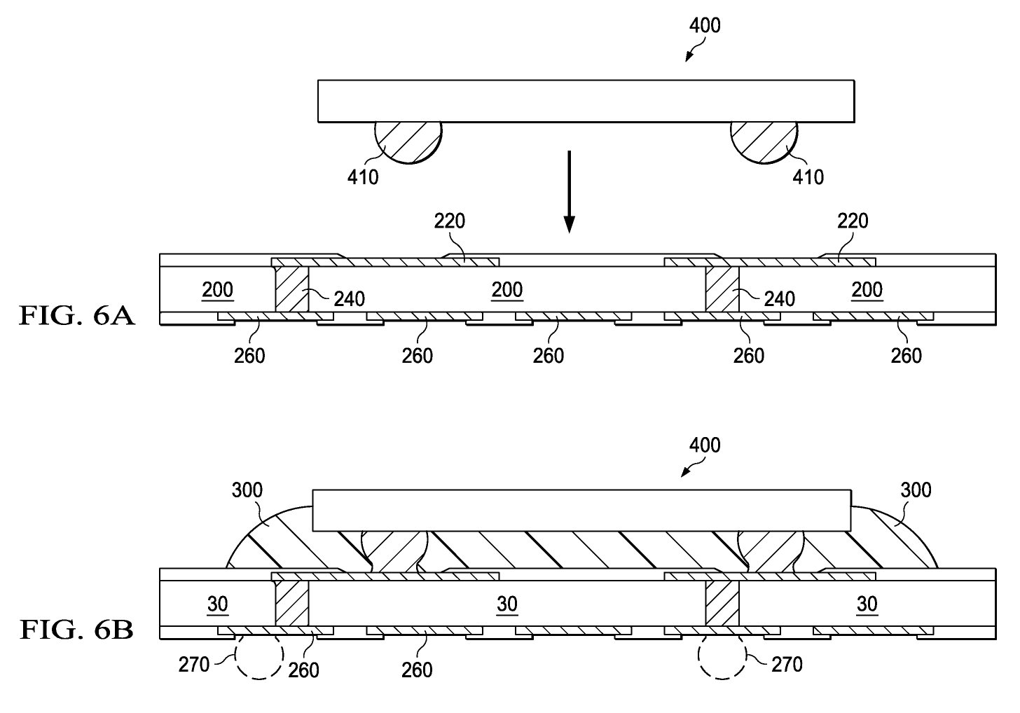

Next, another example of flip-chip mounting will be explained. An example in which a semiconductor chip was flip-chip-mounted on a substrate was shown in the aforementioned embodiment. Now, FIG. 6 shows an example in which a semiconductor package is flip-chip-mounted on a substrate. As shown in said figure, semiconductor package 400, such as a BGA or a CSP, is equipped with multiple external terminals that are arranged in the form of a two-dimensional array on the back surface of the package. External terminals 410 are made of solder, for example. After multiple external terminals 410 are connected to conductive lands 220 formed on the top surface of substrate 200, under-filling resin 300 is filled between package 400 and substrate 200. Under-filling resin 300 is cured at a temperature higher than its glass transition temperature while a prescribed level of pressure is applied to it in the same manner as that described above.

As described above, when under-filling resin 300 filled between semiconductor package 400 and substrate 200 is cured, voids in under-filling resin 300 can be reduced, and the bond strength between the semiconductor package and the substrate can be improved.

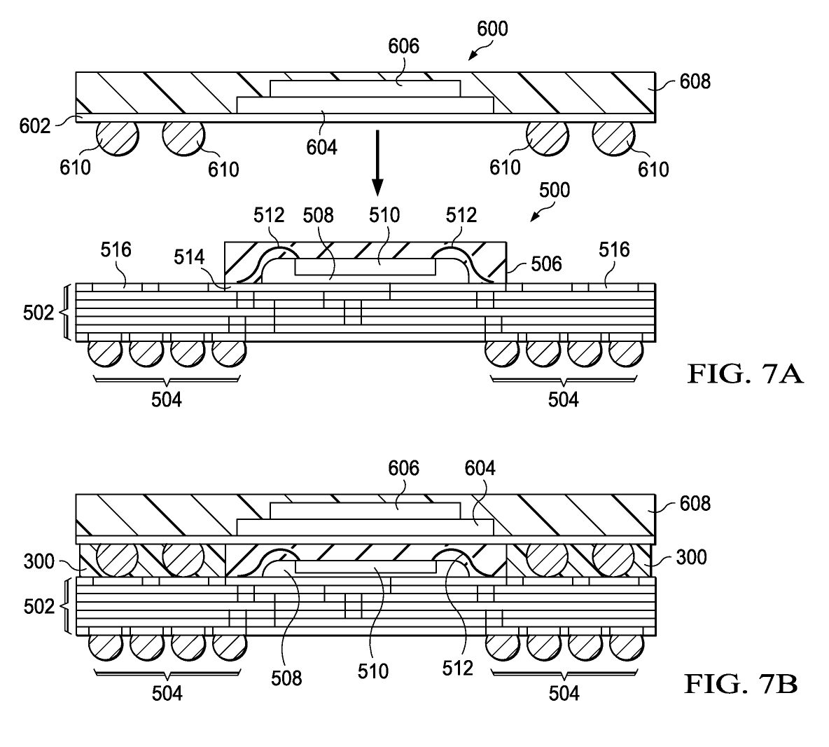

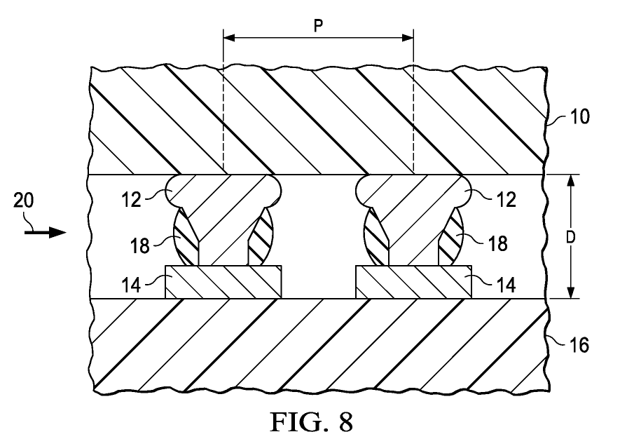

Furthermore, the flip-chip mounting may take the form of package-on-package (POP), wherein another semiconductor package is connected to a semiconductor package. FIG. 7 shows a POP structure in which a BGA package is stacked on top of a BGA package.

First semiconductor package 500 has multilayer wiring board 502, solder balls 504 formed on the back surface of multilayer wiring board 502, and molding resin 506 formed over the top surface of multilayer wiring board 502. Semiconductor chip 510 is installed on the top surface of substrate 502 via die attach 508, and using bonding wires 512, electrodes of semiconductor chip 510 are connected to copper patterns 514 formed on the substrate. The area that contains semiconductor chip 510 and bonding wires 512 is sealed using molding resin 506. In addition to this kind of configuration, semiconductor chip 510 may be flip-chip-connected in the aforementioned manner.

Second semiconductor package 600 is stacked on top of first semiconductor package 500. In the case of second semiconductor package 600, semiconductor chips 604 and 606 are stacked on the top surface of substrate 602, for example; and these semiconductor chips 604 and 606 are sealed using molding resin 608. Solder balls 610 are formed in 2 rows and in 4 directions on the back surface of substrate 602.

Solder balls 610 are arranged in such a manner that they surround molding resin 506 when second semiconductor package 600 is mounted on top of first semiconductor package 500, and solder balls 610 are connected to electrodes 516 that are formed on the top surface of substrate 502. Next, under-filling resin 300 is filled into a gap formed between first semiconductor package 500 and second semiconductor package 600. Under-filling resin 300 is cured in the same manner as that described above. As a result, the bond strength between first package 500 and second package 600 can be improved.

A preferred embodiment of the present invention has been explained in detail above. However, a variety of modifications can be made within the scope of the gist of the present invention described in the Claims without restriction to the specific embodiments pertaining to the present invention.

What is claimed is:

1. A method for manufacturing a semiconductor device, comprising:
placing a resin material into a gap between a surface of a first semiconductor component and a surface of a second semiconductor component;
hardening the under-fill resin material;
heating and pressurizing the under-fill resin material; and
curing the under-filling resin.

2. The method for manufacturing a semiconductor device in claim 1, wherein the heating step includes heating the under-fill resin to a temperature higher than its glass transition temperature.

3. The method for manufacturing a semiconductor device in claim 1, wherein the under-fill resin is an epoxy resin filled with silica.

4. The method for manufacturing a semiconductor device in claim 3, wherein the viscosity of the under-fill resin is 60 Pa·s or higher before curing.

5. The method for manufacturing a semiconductor device of claim 4, wherein the gap is 50 microns or less.

6. The method for manufacturing a semiconductor device of claim 4, wherein the surface of the first semiconductor component includes electrodes at a pitch of 50 microns or less.

7. The method for manufacturing a semiconductor device in claim 1, wherein the heating and pressurizing step further includes placing the semiconductor device inside a chamber.

8. The method for manufacturing a semiconductor device in claim 7, wherein the curing step further includes maintaining the semiconductor device in the chamber.

9. The method for manufacturing a semiconductor device in claim 1, wherein the placing step further includes injecting the resin from one side surface of the first semiconductor component or at a corner of two side surfaces of the first semiconductor component.

10. The method for manufacturing a semiconductor device in claim 1, in which the first semiconductor component is a semiconductor chip.

11. The method for manufacturing a semiconductor device in claim 10, in which the second semiconductor component is an insulating substrate.

12. The method for manufacturing a semiconductor device in claim 1, in which the first semiconductor component is a first semiconductor chip package.

13. The method for manufacturing a semiconductor device in claim 12, in which the second semiconductor component is a second semiconductor chip package.

14. The method for manufacturing a semiconductor device in claim 1, in which the first and the second semiconductor component are further connected by conductive connectors.

15. The method for manufacturing a semiconductor device in claim 14, in which the conductive connectors include solder.

16. The method for manufacturing a semiconductor device in claim 14, in which the conductive connectors include gold studs.
